(19) United States
(12) Patent Application Publication
(10) Pub. No.: US 2025/0008742 A1
(43) Pub. Date: Jan. 2, 2025

(54) SEMICONDUCTOR DEVICE AND METHOD FOR FABRICATING THE SAME

(71) Applicant: SK hynix Inc., Icheon-si (KR)

(72) Inventors: Jong Min YUN, Icheon-si (KR); Cha Deok DONG, Icheon-si (KR)

(21) Appl. No.: 18/393,449

(22) Filed: Dec. 21, 2023

(30) Foreign Application Priority Data
Jun. 29, 2023 (KR) 10-2023-0084346

(51) Int. Cl. H10B 61/00; H10N 50/01

(52) U.S. Cl. CPC H10B 61/00; H10N 50/01

(57) ABSTRACT

A semiconductor device and a method for fabricating the same are provided. The semiconductor device includes: a substrate; a pattern disposed over the substrate; a hard mask pattern that is conductive and disposed over the pattern, the hard mask pattern including a lower hard mask pattern and an upper hard mask pattern over the lower hard mask pattern; a conductive pattern disposed over the hard mask pattern and electrically connected to the pattern through the hard mask pattern; and an insulating layer covering a sidewall of the pattern and a sidewall of the lower hard mask pattern, wherein the upper hard mask pattern is disposed to protrude from the insulating layer.

### PRIORITY CLAIM AND CROSS-REFERENCE TO RELATED APPLICATION

This patent document claims priority under 35 U.S.C. § 119 to Korean Patent Application No. 10-2023-0084346 filed on Jun. 29, 2023, which is incorporated herein by reference in its entirety.

### TECHNICAL FIELD

This patent document relates to a semiconductor technology, and particularly, to a semiconductor device including a conductive hard mask and a method for fabricating the same.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

In an embodiment, a semiconductor device may include: a substrate; a pattern disposed over the substrate; a hard mask pattern that is conductive and disposed over the pattern, the hard mask pattern including a lower hard mask pattern and an upper hard mask pattern over the lower hard mask pattern; a conductive pattern disposed over the hard mask pattern and electrically connected to the pattern through the hard mask pattern; and an insulating layer covering a sidewall of the pattern and a sidewall of the lower hard mask pattern, wherein the upper hard mask pattern is disposed to protrude from the insulating layer.

In another embodiment, a method for fabricating a semiconductor device, may include: forming an etching target layer over a substrate; forming an initial hard mask pattern over the etching target layer, the initial hard mask pattern including a conductive material; forming a pattern by etching the etching target layer using the initial hard mask pattern as an etching barrier; forming an insulating layer that fills a space between the pattern and another pattern adjacent to the pattern and exposes the initial hard mask pattern; exposing the initial hard mask pattern to a first element to form a hard mask pattern with a volume greater than a volume of the initial hard mask pattern; and forming a conductive pattern over the hard mask pattern.

### BRIEF DESCRIPTION OF THE DRAWINGS

FIGS. 1A to 6B are example views illustrating a semiconductor device according to an embodiment of the present disclosure, and an example method for fabricating the semiconductor device.

FIG. 7 is a cross-sectional view illustrating an example of a memory layer.

FIG. 8 is a cross-sectional view illustrating a semiconductor device of a comparative example.

FIG. 9 is a cross-sectional view illustrating a semiconductor device according to another embodiment of the present disclosure, and a method for fabricating the semiconductor device.

FIG. 10 is a cross-sectional view illustrating a semiconductor device according to another embodiment of the present disclosure, and a method for fabricating the semiconductor device.

FIGS. 11 and 12 are cross-sectional views illustrating a semiconductor device according to another embodiment of the present disclosure, and a method for fabricating the semiconductor device.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

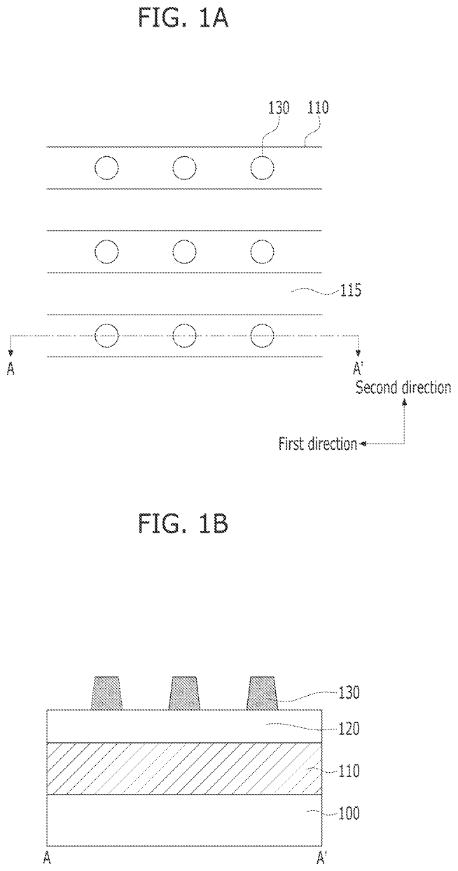

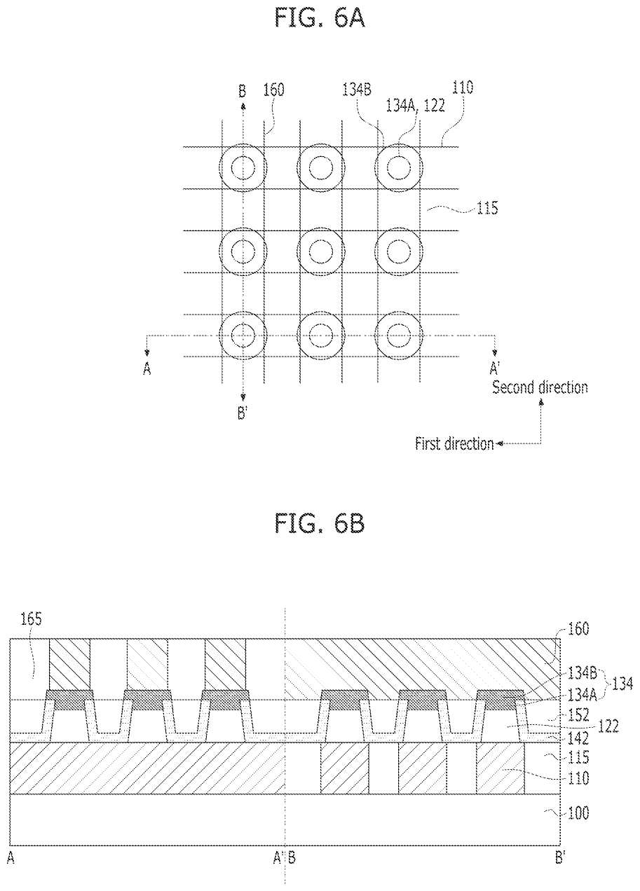

FIGS. 1A to 6B are views illustrating a semiconductor device according to an embodiment of the present disclosure, and a method for fabricating the same. FIGS. 1A, 2A, 5A, and 6A are plan views, and FIGS. 1B, 2B, 3, 4, 5B, and 6B are cross-sectional views. FIGS. 1B, 2B, and 5B are cross-sectional views taken along a line A-A′ of FIGS. 1A, 2A, and 5A, respectively, and FIG. 6B is a cross-sectional view taken along lines A-A′ and B—B′ of FIG. 6A.

First, the fabricating method will be explained.

Referring to FIGS. 1A and 1B, a substrate 100 may be provided. The substrate 100 may include a semiconductor material such as silicon. Additionally, a lower structure (not shown) may be formed within the substrate 100. For example, an integrated circuit for driving the first conductive line 110 and/or the second conductive line (see 160 in FIGS. 6A and 6B), which will be described later, may be formed in the substrate 100.

Subsequently, a first conductive line 110 extending in a first direction may be formed over the substrate 100. A plurality of first conductive lines 110 may be arranged to be spaced apart from each other in a second direction intersecting the first direction. Here, the first direction and the second direction may mean a direction substantially parallel to the upper surface of the substrate 100, that is, a horizontal direction. A direction substantially perpendicular to the upper surface of the substrate 100 will hereinafter be referred to as a vertical direction. The space between the first conductive lines 110 may be filled with a first insulating layer 115. As an example, the first conductive line 110 and the first insulating layer 115 may be formed by depositing a conductive material for forming the first conductive line 110 over the substrate 100, selectively etching the conductive material to form the first conductive line 110, depositing an insulating material thick enough to cover the first conductive line 110 while filling the space between the first conductive lines 110, and performing a planarization process, for example, CMP (Chemical Mechanical Polishing) so that the upper surface of the first conductive line 110 is exposed. In another example, the first conductive line 110 and the first insulating layer 115 may be formed by depositing an insulating material for forming the first insulating layer 115 over the substrate 100, selectively etching the insulating material to form the first insulating layer 115 that provides a space in which the first conductive line 110 is to be filled, depositing a conductive material having a thickness covering the first insulating layer 115 while filling the space, and performing a planarization process so that the upper surface of the first insulating layer 115 is exposed. The first conductive line 110 may include at least one of various conductive materials, for example, a metal such as platinum (Pt), tungsten (W), aluminum (Al), copper (Cu), or tantalum (Ta), a metal nitride such as titanium nitride (TiN) or tantalum nitride (TaN), or a combination thereof. The first insulating layer 115 may include at least one of various insulating materials, for example, silicon oxide, silicon nitride, silicon oxynitride, or a combination thereof.

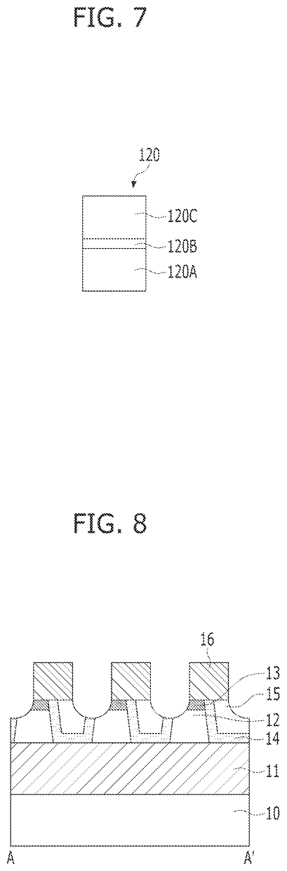

Subsequently, a memory layer 120 may be formed over the first conductive line 110 and the first insulating layer 115. The memory layer 120 may be a layer that functions to store data in various ways and may have a single-layer structure or a multi-layer structure. As an example, the memory layer 120 may include a variable resistance layer that stores different data by switching between different resistance states. The variable resistance layer may have a single-layer structure or a multi-layer structure including at least one of various materials used in RRAM, PRAM, FRAM, MRAM, or others, for example, a metal oxide such as a transition metal oxide or a perovskite material, a phase change materials such as a chalcogenide material, a ferroelectric material, a ferromagnetic materials, etc. Furthermore, as an example, the memory layer 120 may include a magnetic tunnel junction structure, which will be described in more detail with reference to FIG. 7.

FIG. 7 is a cross-sectional view illustrating an example of the memory layer 120.

Referring to FIG. 7, the memory layer 120 may include a magnetic tunnel junction structure including a stacked structure of a pinned layer 120A, a tunnel barrier layer 120B, and a free layer 120C. The pinned layer 120A may be a layer that has a fixed magnetization direction to be compared to the magnetization direction of the free layer 120C, and may also be called a reference layer. The free layer 120C may be a layer that stores different data by having a changeable magnetization direction, and may also be called a storage layer. Each of the pinned layer 120A and the free layer 120C may have a magnetization direction substantially parallel to the surface of the layer, i.e., a horizontal magnetization direction, or may have a magnetization direction substantially perpendicular to the surface of the layer, i.e., a perpendicular magnetization direction. The tunnel barrier layer 120B may physically separate the pinned layer 120A and the free layer 120C, and may enable tunneling of electrons between the pinned layer 120A and the free layer 120C. Each of the pinned layer 120A and the free layer 120C may independently have a single-layer structure or a multi-layer structure including a ferromagnetic material. In an example, each of the pinned layer 120A and the free layer 120C may independently include an alloy containing Fe, Ni, or Co as a main component, for example, Fe—Pt alloy, Fe—Pd alloy, Co—Pd alloy, Co—Pt alloy, Fe—Ni—Pt alloy, Co—Fe—Pt alloy, Co—Ni—Pt alloy, or Co—Fe—B alloy, or a stacked structure of Co/Pt or Co/Pd. The tunnel barrier layer 120B may have a single-layer structure or a multi-layer structure including an insulating material. In an example, the tunnel barrier layer 120B may include an insulating oxide such as MgO, CaO, SrO, TiO, VO, or NbO. The magnetization direction of the free layer 120C may vary depending on the voltage or current applied to the memory layer 120. When the magnetization direction of the free layer 120C is parallel to the magnetization direction of the pinned layer 120A, the memory layer 120 may have a low resistance state and, for example, may store data ‘1’. On the other hand, when the magnetization direction of the free layer 120C is anti-parallel to the magnetization direction of the pinned layer 120A, the memory layer 120 may have a high resistance state and, for example, may store data ‘0’. In another implementation, the data ‘0’ can be stored when the magnetization direction of the free layer 120C is anti-parallel to the magnetization direction of the pinned layer 120A and the data ‘1’ can be stored when the magnetization direction of the free layer 120C is parallel to the magnetization direction of the pinned layer 120A.

As long as the memory layer 120 includes the pinned layer 120A, the free layer 120C, and the tunnel barrier layer 120B between the pinned layer 120A and the free layer 120C, the layer structure of the memory layer 120 may be modified in various ways. In an example, the positions of the pinned layer 120A and the free layer 120C may be reversed with each other. Alternatively, in an example, although not shown, the memory layer 120 may further include one or more layers to improve the characteristics of the magnetic tunnel junction structure.

Referring again to FIGS. 1A and 1B, an initial hard mask pattern 130 for patterning the memory layer 120 may be formed over the memory layer 120. In an example, the initial hard mask pattern 130 may have an island shape in order to pattern the memory layer 120 into a pillar shape. A plurality of initial hard mask patterns 130 may be arranged in a matrix form along the first and second directions. The plurality of initial hard mask patterns 130 arranged in the first direction may overlap the corresponding first conductive line 110.

In the implementations, the initial hard mask pattern 130 may include a conductive material whose volume increases when reacted with a specific element. For example, the initial hard mask pattern 130 may include a metal or alloy that can expand when reacted with hydrogen. For example, the metal or alloy may include V, Pd, LaNi₅, TiMn₂, TiFe, or a combination thereof. It is already well known that when each of V, Pd, LaNi₅, TiMn₂, and TiFe is exposed to H₂ gas, it reacts with hydrogen and results in volume expansion, so a detailed description thereof will be omitted.

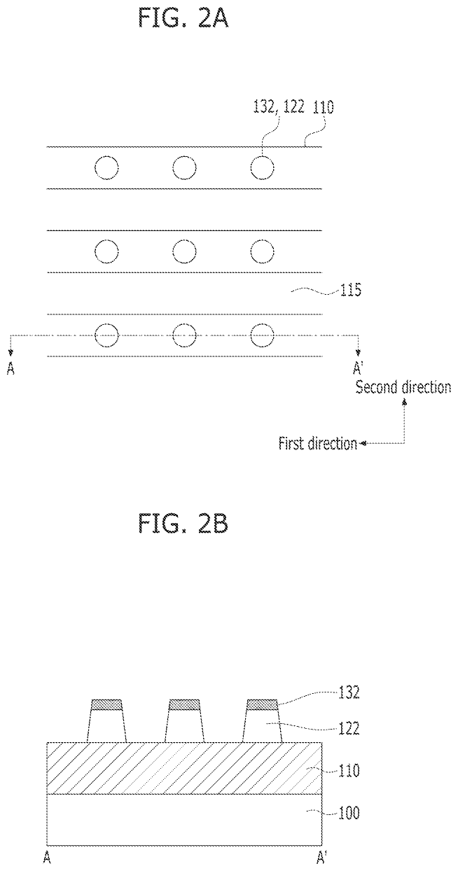

Referring to FIGS. 2A and 2B, the memory layer 120 may be etched using the initial hard mask pattern 130 as an etching barrier to form a memory pattern 122. In this process, portions of the initial hard mask pattern 130 may be lost and the thickness of the initial hard mask pattern 130 may be reduced. The initial hard mask pattern with reduced thickness is denoted by a reference numeral 132. In some implementations, however, the loss of the initial hard mask pattern 130 may rarely occur. In this case, the initial hard mask pattern 130 may be hardly lost, and thus, most of the initial hard mask pattern 130 may be maintained.

In the implementations, the memory pattern 122 may have a pillar shape, and a plurality of memory patterns 122 may be arranged in a matrix form along the first and second directions. The plurality of memory patterns 122 arranged in the first direction may overlap the first conductive line 110, and may be electrically connected to the first conductive line 110. The initial hard mask pattern 132 may overlap each memory pattern 122 on each memory pattern 122.

The etching process for forming the memory pattern 122 may be performed in various ways, such as ion beam etching (IBE) or reactive ion etching (RIE).

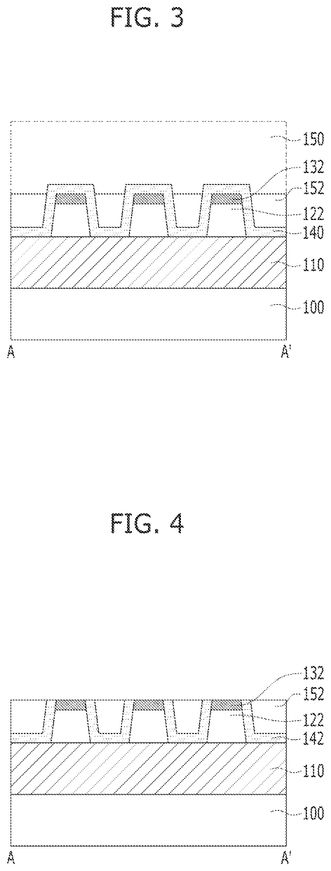

Referring to FIG. 3, a protective layer 140 may be formed conformally along the lower profile over the process result of FIG. 2. Accordingly, the protective layer 140 may be formed to cover the sidewall and the upper surface of the initial hard mask pattern 132, the sidewall of the memory pattern 122, and the upper surface of the first conductive line 110 that is not covered by the memory pattern 122.

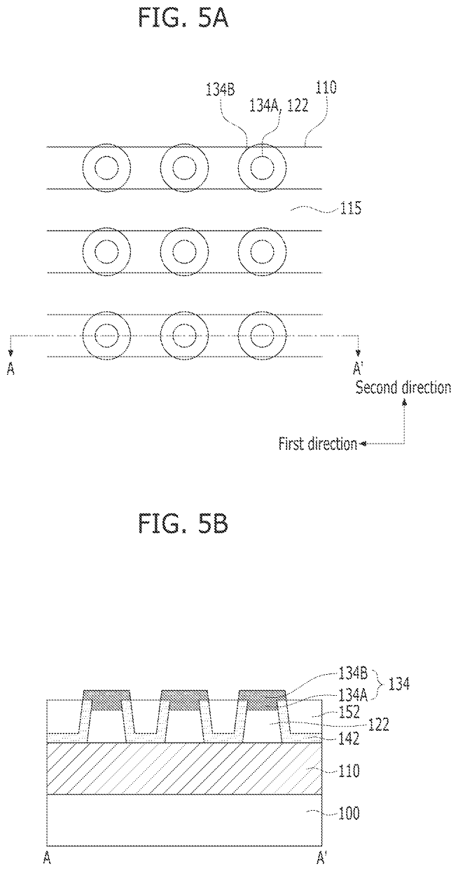

The protective layer 140 may function to prevent elements used during the subsequent forming process of a hard mask pattern (see FIGS. 5A and 5B) from penetrating into the memory pattern 122 and deteriorating the characteristics of the memory pattern 122. For example, if the memory pattern 122 includes a magnetic tunnel junction structure, it may be deteriorated due to exposure to hydrogen. By having the protective layer 140 over the memory pattern 122, it is possible to prevent the memory pattern 122 from being exposed to hydrogen. Thus, the protective layer 140 can prevent this deterioration of the memory pattern 122. The protective layer 140 may include silicon nitride. However, the present disclosure is not limited thereto, and various insulating materials that can prevent elements such as hydrogen from penetrating into the memory pattern 122 may be used as the protective layer 140.

Subsequently, a second insulating layer 150 may be formed over the protective layer 140 with a thickness that sufficiently covers the protective layer 140. The second insulating layer 150 may include an insulating material different from the protective layer 140, and may include an insulating material that has better gap-fill characteristics than the protective layer 140. As an example, the second insulating layer 150 may include silicon oxide.

Subsequently, an upper portion of the second insulating layer 150 may be removed to form a second insulating pattern 152. After removing the upper portion of the second insulating layer 150, some portions of the protective layer 140 can be exposed. The removed upper portion of the second insulating layer 150 is indicated with a dotted line. The upper surface of the second insulating pattern 152 may be located at a height that is equal to or lower than the height of the uppermost surface of the protective layer 140. For reference, the uppermost surface of the protective layer 140 may refer to a surface which is located on the upper surface of the initial hard mask pattern 132 and has the greatest height from the upper surface of the substrate 100. In some implementations, the upper surface of the second insulating pattern 152 may be located at a height that is equal to or greater than the height of the upper surface of the memory pattern 122. If the height of the upper surface of the second insulating pattern 152 is lower than the height of the upper surface of the memory pattern 122, the uppermost surface of a protective pattern may also be lowered during the subsequent forming process of the protective pattern (see FIG. 4), thereby exposing a portion of the sidewall of the memory pattern 122.

The removal of the upper portion of the second insulating layer 150 may be performed using a planarization process such as CMP, and may be performed by aiming to expose the upper surface of the protective layer 140.

Referring to FIG. 4, a portion of the protective layer 140 exposed by the second insulating pattern 152 may be removed to form a protective pattern 142 exposing the initial hard mask pattern 132. The uppermost surface of the protective pattern 142 may be located at a height that is equal to or lower than the height of the upper surface of the initial hard mask pattern 132. In some implementations, the uppermost surface of the protective pattern 142 may be located at a height that is greater than or equal to the height of the upper surface of the memory pattern 122. This is because if the height of the upper surface of the protective pattern 142 is lower than the height of the upper surface of the memory pattern 122, a portion of the sidewall of the memory pattern 122 is exposed and cannot be protected by the protective pattern 142. In this embodiment, the upper surface of the second insulating pattern 152, the uppermost surface of the protective pattern 142, and the upper surface of the initial hard mask pattern 132 are located at a substantially same height to form a flat surface. However, the present disclosure is not limited thereto, and the heights of these upper surfaces may be somewhat different from one another.

The partial removal of the protective layer 140 may be performed through a process such as etch-back, and may be performed with the target of exposing the upper surface of the initial hard mask pattern 132. Although not shown, after the partial removal of the protective layer 140, a cleaning process may be further performed to expose the upper surface of the initial hard mask pattern 132.

In this embodiment, the partial removal of the second insulating layer 150 and the partial removal of the protective layer 140 are performed in separate processes. The present disclosure, however, is not limited thereto, and the partial removal of the second insulating layer 150 and the partial removal of the protective layer 140 may be performed in a single process. For example, after forming the second insulating layer 150 as shown in FIG. 3, a planarization process may be performed on the second insulating layer 150 and the protective layer 140 to expose the upper surface of the initial hard mask pattern 132, and thus, the process result as shown in FIG. 4 may be obtained.

Referring to FIGS. 5A and 5B, the process result of FIG. 4 may be exposed to an element. The element has the characteristic to cause the volume expansion of the initial hard mask pattern 132 expand by reacting with the initial hard mask pattern 132. Hereinafter, the element will be referred to as a first element. Assume that the initial hard mask pattern 132 includes a metal or alloy such as V, Pd, LaNi₅, TiMn₂, TiFe, or a combination thereof, whose volume can expand upon reaction with hydrogen. The process result of FIG. 4 may be exposed to a hydrogen-containing gas, for example, H₂ gas. By the reaction with the hydrogen, the volume of the initial hard mask pattern 132 may expand.

As a result of this process, a hard mask pattern 134 is formed, which is larger than the initial hard mask pattern 132. A volume of the hard mask pattern 134 is greater than the volume of the initial hard mask pattern 132. Thus, the hard mask pattern 134 has the increase volume compared to the initial hard mask pattern 132.

The hard mask pattern 134 may include constituent elements of the initial hard mask pattern 132 and the first element. For example, the hard mask pattern 134 may include a material that includes a metal or alloy forming the initial hard mask pattern 132 and hydrogen. For example, the hard mask pattern 134 may include a hydride of the metal or alloy. The hard mask pattern 134 may still be conductive. In an example, the hydride of the metal or alloy forming the hard mask pattern 134 may be conductive.

The expansion of the initial hard mask pattern 132 may initially occur in the vertical direction, and accordingly, the thickness may expand. This is because the sidewall of the initial hard mask pattern 132 is surrounded by the protective pattern 142. When the initial hard mask pattern 132 is expanded to form a part that protrudes upward, the expansion proceeds in the horizontal direction as well as in the vertical direction by using the protruding part that has been formed by the initial expansion in the vertical direction. Accordingly, expansion in the thickness and the width may occur. As a result, the hard mask pattern 134 as shown in FIG. 6B may be formed. The hard mask pattern 134 may include a lower hard mask pattern 134A whose sidewall is surrounded by the protective pattern 132, and an upper hard mask pattern 134B that is located over the lower hard mask pattern 134A and has a width greater than a width of the lower hard mask pattern 134A. The sidewall of the lower hard mask pattern 134A may be aligned with the sidewall of the memory pattern 122. The thickness of the hard mask pattern 134 may be greater than the thickness of the initial hard mask pattern 132, and the width of the upper hard mask pattern 134B may be greater than the width of the initial hard mask pattern 132. The width of the lower hard mask pattern 134A may be substantially the same as the width of the initial hard mask pattern 132.

The upper hard mask pattern 134B may be positioned over the protective pattern 142 and the second insulating pattern 152 in the vertical direction. Since the upper hard mask pattern 134B has a width larger than the lower hard mask pattern 134A, it may cover at least a portion of the uppermost surface of the protective pattern 142. In this embodiment, the upper hard mask pattern 134B is shown as covering the entire uppermost surface of the protective pattern 142 and having a sidewall aligned with the outer sidewall of the protective pattern 142, but the present disclosure is not limited thereto. As long as the upper hard mask pattern 134B covers at least a portion of the uppermost surface of the protective pattern 142, the width of the upper hard mask pattern 134B may be adjusted in various ways. For example, in another embodiment, the upper hard mask pattern 134B may have a width smaller than shown to cover a portion of the uppermost surface of the protective pattern 142, or may have a width greater than shown to cover the entire uppermost surface of the protective pattern 134B and a portion of the upper surface of the second insulating pattern 152. Even in this case, the width of the upper hard mask pattern 134B may be limited to not connecting and/or contacting another upper hard mask pattern 134B adjacent thereto in the first direction or second direction.

Referring to FIGS. 6A and 6B, a second conductive line 160 extending in the second direction may be formed over the process result of FIGS. 5A and 5B. A plurality of second conductive lines 160 may be arranged to be spaced apart from each other in the first direction. The second conductive line 160 may overlap and be electrically connected to the plurality of memory patterns 122 arranged in the second direction. The second conductive line 160 may not directly contact the memory pattern 122 but may be electrically connected to the memory pattern 122 through the hard mask pattern 134.

The space between the second conductive lines 160 may be provided for forming a third insulating layer 165. Thus, the space between the second conductive lines 160 may be filled with a third insulating layer 165. In an example, the second conductive line 160 and the third insulating layer 165 may be formed by depositing a conductive material for forming the second conductive line 160 over the process result of FIGS. 5A and 5B, selectively etching the conductive material to form the second conductive line 160, depositing an insulating material thick enough to cover the second conductive line 160 while filling the space between the second conductive lines 160, and performing a planarization process such as CMP to expose the upper surface of the second conductive line 160. Alternatively, as another example, the second conductive line 160 and the third insulating layer 165 are formed by depositing an insulating material for forming the third insulating layer 165 over the process result of FIGS. 5A and 5B, selectively etching the insulating material to form the third insulating layer 165 that provides a space in which the second conductive line 160 is to be filled, depositing a conductive material thick enough to cover the third insulating layer 165 while filling this space, and performing a planarization process to expose the upper surface of the third insulating layer 165. The second conductive line 160 may include at least one of various conductive materials, for example, a metal such as platinum (Pt), tungsten (W), aluminum (Al), copper (Cu), or tantalum (Ta), a metal nitride such as titanium nitride (TiN) or tantalum nitride (TaN), or a combination thereof. The third insulating layer 165 may include at least one of various insulating materials, for example, silicon oxide, silicon nitride, silicon oxynitride, or a combination thereof.

Since the second conductive line 160 is formed over the second insulating pattern 152 and the hard mask pattern 134 protruding above the second insulating pattern 152, the height of the lower surface of a portion of the second conductive line 160 in a region overlapping the hard mask pattern 134 may be higher than the height of the lower surface of the remaining portion of the second conductive line 160.

By the fabricating method described above, the semiconductor device shown in FIGS. 6A and 6B may be manufactured.

Referring again to FIGS. 6A and 6B, the semiconductor device of this embodiment may include the substrate 100, the plurality of first conductive lines 110 disposed over the substrate 100 and extending in the first direction, the plurality of second conductive lines 160 disposed over the plurality of first conductive lines 110 and extending in the second direction, the plurality of memory patterns 122 respectively overlapping the intersection regions of the plurality of first conductive lines 110 and the plurality of second conductive lines 160 therebetween, the hard mask pattern 134 overlapping each of the memory patterns 122 thereover and including the stacked structure of the lower hard mask pattern 134A and the upper hard mask pattern 134B, and the protective pattern 142 covering the sidewall of the lower hard mask pattern 134A and the sidewall of the memory pattern 122.

Here, the upper hard mask pattern 134B may protrude above the protective pattern 142, and the width of the upper hard mask pattern 134B may be greater than the width of the lower hard mask pattern 134A. The upper hard mask pattern 134B may cover at least a portion of the uppermost surface of the protective pattern 142. Furthermore, the upper hard mask pattern 134B may further cover a portion of the upper surface of the second insulating pattern 152 filling a space defined by the protective patterns 142. Also, the hard mask pattern 134 may include a conductive material and a certain element that increases the volume of the conductive material. For example, the hard mask pattern 134 may include a metal or alloy such as V, Pd, LaNi₅, TiMn₂, TiFe, or a combination thereof, and hydrogen to increase the volume of the metal or alloy.

Since the components of the semiconductor device of this embodiment have been described in detail in the process of explaining the above-described fabricating method, further detailed description will be omitted.

According to the implementations of the semiconductor device and its fabricating method, which are described above, the following advantages can be obtained.

Even if the thickness of the initial hard mask pattern 132 remaining after etching the memory layer 120 is thin, the volume of the initial hard mask pattern 132 may expand and then the second conductive line 160 may be formed. Therefore, the alignment between the hard mask pattern 134 and the second conductive line 160 may be facilitated. Further, even if the misalignment between the hard mask pattern 134 and the second conductive line 160 occurs, defects due to the misalignment may be reduced and/or prevented. This will be examined in more detail by referring to a comparative example described below.

FIG. 8 is a cross-sectional view illustrating a semiconductor device of a comparative example.

Referring to FIG. 8, the semiconductor device of the comparative example may include a substrate 10, a first conductive line 11, a memory pattern 12, a hard mask pattern 13, a protective pattern 14, an insulating pattern 15, and a second conductive line 16. The difference from the present embodiment is that the second conductive line 16 is formed immediately after performing a process substantially the same as the process of FIG. 4 without any expansion of the hard mask pattern 13. In this case, the width of the hard mask pattern 13 is small, so the possibility of misalignment with the second conductive line 16 may increase. In addition, as shown, when the misalignment occurs between the hard mask pattern 13 and the second conductive line 16, a portion of the hard mask pattern 13 that is exposed by the second conductive line 16 may be lost during the etching process of the conductive material for forming the second conductive line 16. In this case, since the thickness of the hard mask pattern 13 is small, the loss of the memory pattern 12 may occur due to the loss of the hard mask pattern 13. As a result, the characteristics of the memory pattern 12 may be adversely affected.

In the present embodiment, since the second conductive line 160 is formed over the hard mask pattern 134 whose thickness and width are expanded by the expansion of the initial hard mask pattern 132, the alignment between the upper hard mask pattern 134B and the second conductive line 160 may be easier than in the comparative example. In addition, even if the misalignment occurs between the second conductive line 160 and the hard mask pattern 134 so that the hard mask pattern 134 is lost, the thickness of the hard mask pattern 134 is larger than that of the comparative example, and thus, the possibility of exposure and loss of the memory pattern 120 can be reduced.

In addition, in this embodiment, since the expansion process of the initial hard mask pattern 132 occurs, there is more flexibility to design the initial hard mask pattern 132 with a certain thickness without the need to increase the thickness of the initial hard mask pattern 130 much. The thickness of the initial hard mask pattern 132 may be sufficient as long as it remains on the memory pattern 122 at a thin thickness after the memory layer 120 is etched. If the thickness of the initial hard mask pattern 130 is too large, there is an undesired problem due to the shadow effect that occurs in the IBE process, which make not only the area to be etched but also adjacent areas obscure, thereby making hard to perform an etching process. However, in the present embodiment, since there is no need to increase the thickness of the initial hard mask pattern 130, it is possible to avoid and prevent the undesired problem caused from the shadow effect in the IBE process.

Thus, according to the implementations of the semiconductor device and its fabricating method of the present embodiment, the characteristics of the semiconductor device can be secured, and process defects can be prevented and/or reduced.

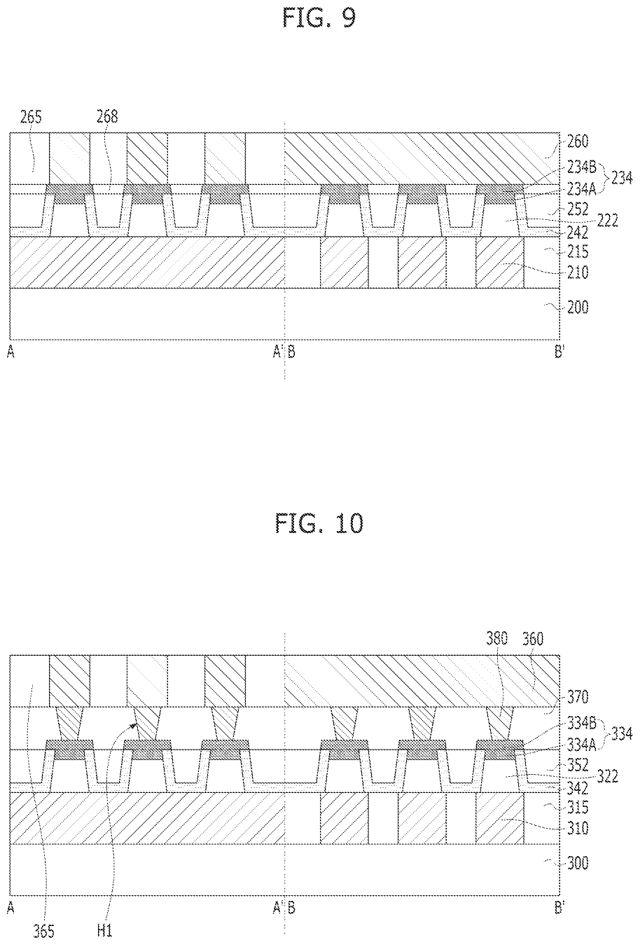

FIG. 9 is a cross-sectional view illustrating a semiconductor device according to another embodiment of the present disclosure, and a method for fabricating the same. The description will focus on differences from the embodiment of FIGS. 1A to 6B described above.

Referring to FIG. 9, substantially the same processes as the processes of FIGS. 1A to 5B described above may be performed to obtain a structure including a substrate 200, a first conductive line 210, a first insulating layer 215, a memory pattern 222, a hard mask pattern 234 including a lower hard mask pattern 234A and an upper hard mask pattern 234B, a protective pattern 242, and a second insulating pattern 252.

Subsequently, after depositing an insulating material covering the second insulating pattern 252 and the hard mask pattern 234, a planarization process may be performed to expose the upper surface of the hard mask pattern 234. As a result, a fourth insulating layer 268 may be formed to fill a space between the upper hard mask patterns 234B. The upper surface of the fourth insulating layer 268 and the upper surface of the hard mask pattern 234 may form a flat surface located at substantially the same height.

Subsequently, a process for forming the second conductive line 160 and the third insulating layer 165 may be performed. Since the flat surface is located under the second conductive line 160 and the third insulating layer 165, the deposition process, etching process, etc. for forming the second conductive line 160 and the third insulating layer 165 may be performed more easily.

In this embodiment, the fourth insulating layer 268 that fills the space between the upper hard mask patterns 234B and has the upper surface forming a flat surface with the upper surface of the hard mask pattern 234, may further be interposed between the second conductive line 260 and the second insulating pattern 252, and accordingly, the height of the lower surface of the second conductive line 260 may be substantially constant.

FIG. 10 is a cross-sectional view illustrating a semiconductor device according to another embodiment of the present disclosure, and a method for fabricating the same. The description will focus on differences from the embodiment of FIGS. 1A to 6B described above.

Referring to FIG. 10, substantially the same processes as the processes of FIGS. 1A to 5B described above may be performed to obtain a structure including a substrate 300, a first conductive line 310, a first insulating layer 315, a memory pattern 322, a hard mask pattern 334 including a lower hard mask pattern 334A and an upper hard mask pattern 334B, a protective pattern 342, and a second insulating pattern 352.

Subsequently, after depositing an insulating material covering the second insulating pattern 352 and the hard mask pattern 334, the insulating material may be selectively etched to form a fourth insulating layer 370 having a hole H1 exposing the hard mask pattern 334. Even when forming the hole H1, the width of the upper hard mask pattern 334B may be increased, and thus, the alignment between the hole H1 and the upper hard mask pattern 334B may be facilitated. Even if the misalignment occurs between the upper hard mask pattern 334B and the hole H1 and the hard mask pattern 334 is lost, the thickness of the hard mask pattern 334 has increased, so the possibility of exposure and loss of the memory pattern 322 may be reduced.

Subsequently, after forming a conductive material thick enough to fill the hole H1, a planarization process may be performed to expose the upper surface of the fourth insulating layer 370. As a result, a contact plug 380 may be formed. The contact plug 380 may fill the hole H1 and may have an upper surface that forms a flat surface with the upper surface of the fourth insulating layer 370. The contact plug 380 may have a pillar shape that overlaps the hard mask pattern 334.

Subsequently, a process for forming the second conductive line 360 and the third insulating layer 365 may be performed. Since the flat surface is located under the second conductive line 360 and the third insulating layer 365, the deposition process, etching process, etc. for forming the second conductive line 360 and the third insulating layer 365 may be performed more easily.

In the implementation of the semiconductor device, the contact plug 380 may be interposed between the second conductive line 360 and the hard mask pattern 334, and the second conductive line 360 and the hard mask pattern 334 may be electrically connected through the contact plug 380. Since the fourth insulating layer 370 filling the space between the contact plugs 380 has an upper surface forming a flat surface with the upper surface of the contact plug 380, the height of the lower surface of the second conductive line 360 located on the flat surface may be substantially constant.

Although not shown, another contact plug may be further interposed between the first conductive line 310 and the memory pattern 322 to electrically connect them. The space between the contact plugs may be filled with an insulating material.

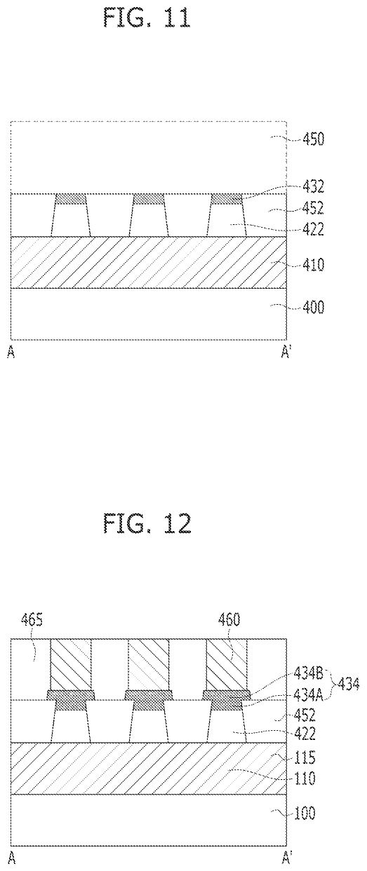

In some implementations, the protective pattern may be omitted. The protective pattern may be skipped in various cases, for example, in a case where the memory layer does not contain a magnetic material and the first element, such as hydrogen, does not significantly affect the memory layer, or in a case where the first element does not affect the magnetic material even if the memory layer contains a magnetic material. This will be described by way of example with reference to FIGS. 11 and 12.

FIGS. 11 and 12 are cross-sectional views illustrating a semiconductor device according to another embodiment of the present disclosure, and a method for fabricating the same. The description will focus on differences from the embodiment of FIGS. 1A to 6B described above.

Referring to FIG. 11, substantially the same processes as the processes of FIGS. 1A to 2B described above may be performed to obtain a structure including a substrate 400, a first conductive line 410, a memory patterns 422, and an initial hard mask patterns 432.

Subsequently, a second insulating layer 450 may be formed with a thickness that sufficiently covers the above structure.

Subsequently, the upper portion of the second insulating layer 450 may be removed to form a second insulating pattern 254 exposing the initial hard mask pattern 432. The removed upper portion of the second insulating layer 450 is indicated with a dotted line. The removal of the upper portion of the second insulating layer 450 may be performed by a planarization process, so that the upper surface of the second insulating pattern 254 is positioned at substantially the same height as the upper surface of the initial hard mask pattern 432.

Referring to FIG. 12, the process result of FIG. 11 may be exposed to a first element that can expand the initial hard mask pattern 432. As a result of this process, a hard mask pattern 434 that is expanded than the initial hard mask pattern 432 may be formed. The hard mask pattern 434 may include a lower hard mask pattern 434A whose sidewall is surrounded by the second insulating pattern 452, and an upper hard mask pattern 434B located over the lower hard mask pattern 434A and having a width greater than the width of the lower hard mask pattern 434A. The upper hard mask pattern 434B may protrude above the second insulating pattern 452 and cover a portion of the upper surface of the second insulating pattern 452.

Subsequently, a process for forming the second conductive line 460 and the third insulating layer 465 may be performed.

The semiconductor device of this embodiment may be different from the above-described embodiment in that the protective pattern is omitted.

In the above-described embodiments, a semiconductor device having a cross-point structure in which a pillar-shaped memory pattern is interposed between two conductive lines spaced apart from each other in the vertical direction and crossing each other in the horizontal direction has been described. However, the present disclosure is not limited thereto. The present disclosure may be applied to any structure formed by providing an etching target layer, forming a pattern having a certain shape by etching the etching target layer using a conductive hard mask pattern as an etching barrier, and forming another conductive pattern over the conductive hard mask pattern to be electrically connected to the pattern through the conductive hard mask pattern. That is, the device of this embodiment may include: a substrate; a pattern disposed over the substrate; a conductive hard mask pattern disposed over the pattern and including a lower hard mask pattern and an upper hard mask pattern over the lower hard mask pattern; a conductive pattern disposed over the hard mask pattern and electrically connected to the pattern through the hard mask pattern; and an insulating layer covering a sidewall of the pattern and a sidewall of the lower hard mask pattern, wherein the upper hard mask pattern protrudes above the insulating layer. Additionally, the fabricating method of the semiconductor device of this embodiment, may include: forming an etching target layer to be etched over a substrate; forming a conductive initial hard mask pattern over the etching target layer; forming a pattern by etching the etching target layer using the initial hard mask pattern as an etching barrier; forming an insulating layer that fills a space between the pattern and another pattern adjacent to the pattern and exposes the initial hard mask pattern; exposing the initial hard mask pattern to a first element to form a hard mask pattern whose volume is increased compared to the initial hard mask pattern; and forming a conductive pattern over the hard mask pattern. In the embodiments of FIGS. 1A to 6B and 9 to 12 described above, the memory layer 110 may correspond to the etching target layer, the memory patterns 122, 222, 322, and 422 may correspond to the pattern, the hard mask patterns 134, 234, 334, and 434 may correspond to the conductive hard mask pattern, and the second conductive lines 160, 260, 360, and 460 may correspond to the conductive pattern. However, the type or shape of the etching target layer and the pattern may be modified in various ways. For example, the pattern may have a pillar shape, a line shape, etc. When the pattern has a line shape, the conductive hard mask pattern also has a line shape that overlaps the pattern, and the width of the upper portion of the conductive hard mask pattern may be greater than the width of the lower portion of the conductive hard mask pattern in the direction intersecting the line. Additionally, the type or shape of the conductive pattern may be modified in various ways. For example, the conductive pattern may have a pillar shape, a line shape, etc.

According to the above embodiments of the present disclosure, it may be possible to secure the characteristics of the semiconductor device and prevent and/or reduce process defects.

Although various embodiments have been described for illustrative purposes, it will be apparent to those skilled in the art that various changes and modifications to the disclosed examples or embodiments and/or other embodiments may be made based on what is described and/or illustrated in this patent document.

What is claimed is:

1. A semiconductor device comprising:
a substrate;
a pattern disposed over the substrate;
a hard mask pattern that is conductive and disposed over the pattern, the hard mask pattern including a lower hard mask pattern and an upper hard mask pattern over the lower hard mask pattern;
a conductive pattern disposed over the hard mask pattern and electrically connected to the pattern through the hard mask pattern; and
an insulating layer covering a sidewall of the pattern and a sidewall of the lower hard mask pattern,
wherein the upper hard mask pattern is disposed to protrude from the insulating layer.

2. The semiconductor device according to claim 1, wherein a width of the upper hard mask pattern is greater than a width of the lower hard mask pattern.

3. The semiconductor device according to claim 1, wherein the sidewall of the lower hard mask pattern and the sidewall of the pattern are aligned with each other.

4. The semiconductor device according to claim 1, wherein the hard mask pattern includes a conductive material and a first element, and
the first element has a characteristic that increases a volume of the conductive material when the first element reacts with the conductive material.

5. The semiconductor device according to claim 4, wherein the conductive material includes V, Pd, LaNi₅, TiMn₂, TiFe, or a combination thereof, and
the first element includes hydrogen.

6. The semiconductor device according to claim 1, wherein the insulating layer includes a protective pattern formed along sidewalls of the pattern and the lower hard mask pattern, and an insulating pattern filling a space defined by the protective pattern.

7. The semiconductor device according to claim 6, wherein the upper hard mask pattern covers at least a portion of an upper surface of the protective pattern.

8. The semiconductor device according to claim 1, wherein the upper hard mask pattern covers a portion of an upper surface of the insulating layer.

9. The semiconductor device according to claim 1, wherein the pattern includes a memory pattern,
the substrate includes a first conductive line extending in a first direction and electrically connected to the pattern, and
the conductive pattern includes a second conductive line extending in a second direction intersecting the first direction.

10. The semiconductor device according to claim 9, wherein the second conductive line is disposed along an upper surface of the insulating layer and a surface of the upper hard mask pattern.

11. The semiconductor device according to claim 9, further comprising:
an additional insulating layer disposed over the insulating layer and having an upper surface forming a flat surface with an upper surface of the upper hard mask pattern,
wherein the second conductive line is disposed over the flat surface.

12. The semiconductor device according to claim 9, further comprising:
an additional insulating layer covering the insulating layer and the upper hard mask pattern; and
a contact plug penetrating the additional insulating layer and in contact with the upper hard mask pattern,
wherein the second conductive line is disposed over the additional insulating layer and the contact plug, and is connected to the upper hard mask pattern through the contact plug.

13. The semiconductor device according to claim 1, wherein the pattern includes a magnetic tunnel junction structure.

14. A method for fabricating a semiconductor device, comprising:
forming an etching target layer over a substrate;
forming an initial hard mask pattern over the etching target layer, the initial hard mask pattern including a conductive material;
forming a pattern by etching the etching target layer using the initial hard mask pattern as an etching barrier;
forming an insulating layer that fills a space between the pattern and another pattern adjacent to the pattern and exposes the initial hard mask pattern;
exposing the initial hard mask pattern to a first element to form a hard mask pattern with a volume greater than a volume of the initial hard mask pattern; and
forming a conductive pattern over the hard mask pattern.

15. The method according to claim 14, wherein the conductive material of the initial hard mask pattern has characteristic whose volume increases when the conductive material reacts with the first element.

16. The method according to claim 15, wherein the conductive material includes V, Pd, LaNi₅, TiMn₂, TiFe, or a combination thereof, and
the first element includes hydrogen.

17. The method according to claim 14, wherein the hard mask pattern has a thickness greater than a thickness of the initial hard mask pattern.

18. The method according to claim 14, wherein the hard mask pattern includes a lower hard mask pattern whose sidewall is surrounded by the insulating layer and an upper hard mask pattern located over the lower hard mask pattern and protruding from the insulating layer.

19. The method according to claim 18, wherein a width of the upper hard mask pattern is greater than a width of the lower hard mask pattern.

20. The method according to claim 14, wherein the pattern includes a memory pattern,
the substrate includes a first conductive line extending in a first direction and electrically connected to the pattern, and
the conductive pattern includes a second conductive line extending in a second direction intersecting the first direction.
